(19) United States
(12) Patent Application Publication
(10) Pub. No.: US 2026/0088808 A1
(43) Pub. Date: Mar. 26, 2026

(54) MERGED DIFFUSION NANOSHEET TRANSISTORS

(71) Applicant: Apple Inc., Cupertino, CA (US)

(72) Inventors: Vivekanandan VENUGOPAL, Saratoga, CA (US); Ajay BHATIA, Saratoga, CA (US)

(21) Appl. No.: 18/945,232

(22) Filed: Nov. 12, 2024

Related U.S. Application Data
(60) Provisional application No. 63/699,329, filed on Sep. 26, 2024.

(51) Int. Cl. H03K 3/356; H01L 27/092; H03K 19/20

(52) U.S. Cl. CPC H03K 3/356104; H10D 84/859; H03K 19/20

(57) ABSTRACT

Different transistor interconnects within a nanosheet to reduce pin capacitance are disclosed. A particular transistor of the transistors formed by a given gate within the nanosheet can be decoupled from the control terminals of the other transistors formed by the given gate to reduce capacitance. Different arrangements of source and drain terminals of the particular transistor are also disclosed.

### CROSS-REFERENCE TO RELATED APPLICATIONS

The present application claims the benefit of U.S. Provisional Application No. 63/699,329, entitled “MERGED DIFFUSION NANOSHEET TRANSISTORS,” filed Sep. 26, 2024, the content of which is incorporated by reference herein in its entirety for all purposes.

### FIELD

This disclosure relates to the field of integrated circuit implementation and, more particularly, to the implementation of logic circuits.

### BACKGROUND

Modern computer systems include multiple circuit blocks designed to perform various functions. For example, such circuit blocks may include processors or processor cores configured to execute software or program instructions. Additionally, the circuit blocks may include memory circuits, mixed-signal or analog circuits, and the like.

Some circuit blocks, e.g., processor or processor cores, include multiple logic circuits. Such logic circuits can include combinatorial and sequential logic circuits implemented using multiple logic gates, e.g., inverter gates, NAND gates, and the like.

Logic gates can be implemented using multiple transistors arranged to implement a desired logic function. Such transistors can include both p-channel transistors and n-channel transistors.

### BRIEF DESCRIPTION OF THE DRAWINGS

FIG. 1 is a block diagram depicting an embodiment of a logic gate.

FIG. 2 is a block diagram depicting an embodiment of a nanosheet.

FIG. 3 is a block diagram depicting a different embodiment of a logic gate.

FIG. 4 is a block diagram depicting another embodiment of a logic gate.

FIG. 5 is a block diagram depicting a particular embodiment of a logic gate.

FIG. 6 is a block diagram depicting an embodiment of a buffer circuit.

FIG. 7A is a block diagram depicting a different embodiment of a nanosheet.

FIG. 7B is a block diagram depicting an embodiment of an arrangement of transistors included in a nanosheet.

FIG. 8 is a block diagram depicting an embodiment of a center drive inverter.

FIG. 9 is a flow diagram depicting an embodiment of a method for operating a logic gate.

FIG. 10 is a block diagram of an embodiment of a device that may include logic gates.

FIG. 11 is a block diagram of various embodiments of computer systems that may include logic gates.

FIG. 12 illustrates an example of a non-transitory computer-readable storage medium that stores circuit design information.

### DETAILED DESCRIPTION

Computer systems can include a variety of logic circuits. As semiconductor process technology has continued to evolve, restrictions have been placed on how transistors are physically implemented. For example, some semiconductor processes mandate a regular structure of both p-type and n-type transistors of the same size. Such regular structures can be referred to as nanosheets. When increased drive is needed, multiple transistors can be connected in parallel.

In some cases, diffusion regions can be shared between two adjacent nanosheets. In some cases, an n-type diffusion region can be shared between two nanosheets while, in other cases, a p-type diffusion region can be shared between the two nanosheets. The shared diffusion regions can allow for larger transistor widths.

To accommodate the larger size of the composite nanosheet, gate routes need to be extended in length. The additional gate route length can result in an increase in pin capacitance for a logic gate implemented by the transistors included in the composite nanosheet. Such an increase in pin capacitance can result in higher power consumption for the logic gate. In some cases, the additional capacitance can also impact performance of the logic gate.

The embodiments illustrated in the drawings and described below provide techniques for reducing pin capacitance in a logic gate implemented with transistors included in a nanosheet with a shared diffusion region. By converting at least one transistor included in the nanosheet to a dummy transistor, the pin capacitance can be reduced without a large impact on performance. Moreover, different transistor interconnect in a nanosheet can also reduce pin capacitance for a logic gate.

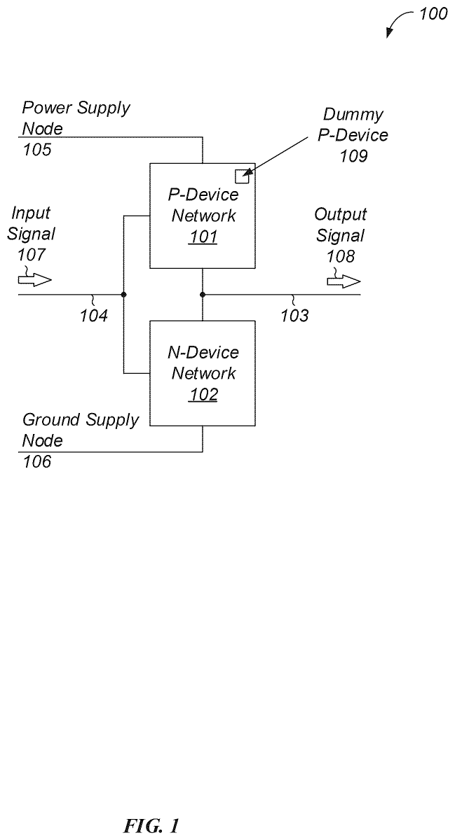

A block diagram of an embodiment of a logic gate is depicted in FIG. 1. As illustrated, logic gate 100 includes p-device network 101 and n-device network 102. In various embodiments, both p-device network 101 and n-device network 102 can include any suitable number of the corresponding type of transistors. As described below, the transistors included in p-device network 101 and n-device network 102 can be implemented in a nanosheet.

P-device network 101 is coupled between power supply node 105 and node 103. A control terminal of p-device network 101 is coupled to node 104 through which input signal 107 is received. N-device network 102 is coupled between node 103 and ground supply node 106. A control terminal of n-device network 102 is also coupled to node 104. In various embodiments, p-device network 101 is configured, based on input signal 107, to source current from power supply node 105 to node 103 to generate output signal 108. In a similar fashion, n-device network 102 can be configured, based on input signal 107, to sink current from node 103 to ground supply node 106 to generate output signal 108.

P-device network 101 includes dummy p-device 109. As described below, dummy p-device 109 may be coupled in different ways to reduce the load on node 104. In some embodiments, how dummy p-device 109 is coupled to power supply node 105 and node 103 may be determined based on leakage power considerations, physical design rules, or any other suitable metric. Although a dummy p-device is depicted in the embodiment of FIG. 1, in other embodiments, a dummy n-device may be used in lieu of dummy p-device 109.

In various embodiments, different arrangements of transistors in p-device network 101 and n-device network 102 can be employed to implement different logic functions for logic gate 100. For example, in some cases, the transistors in p-device network 101 and n-device network 102 can be coupled together to implement an inverter gate, a NAND gate, a NOR gate, or any other suitable logic function. Although a single input signal is depicted, in cases where a logic function of two or more operands is implemented, additional input signals may be employed.

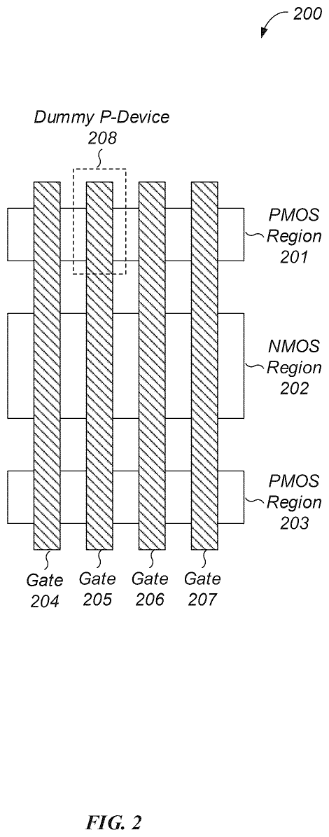

Turning to FIG. 2, a block diagram of an embodiment of a nanosheet is depicted. As illustrated, nanosheet 200 includes two regions doped with p-type dopants (denoted as “PMOS region 201” and “PMOS region 203”), a region doped with n-type dopants (denotes as “NMOS region 202”), and gates 204-207.

NMOS region 202 is disposed between PMOS region 201 and PMOS region 203. Gates 204-207 are disposed orthogonally to NMOS region 202 and PMOS regions 201 and 203. Although only four gates are depicted in the embodiment of FIG. 2, in other embodiments, any suitable number of gates may be employed.

The intersection of gates 204-207 with the PMOS region 201, NMOS region 202, and PMOS region 203 form transistors that can be coupled together using various metal layers to form logic gates. For a given gate, e.g., gate 205, the transistors formed at the overlap with PMOS region 201, NMOS region 202, and PMOS region 203 can share a common control terminal. In the case of gate 205, the transistor formed at the overlap of gate 205 and PMOS region 201 can be used as a dummy device, i.e., dummy p-device 208. In various embodiments, dummy p-device 208 may correspond to dummy p-device 109 as depicted in the embodiment of FIG. 1. As described below different control, source, and drain terminal connections may be employed for dummy p-device 208. In some cases, the control terminal of dummy p-device 208 may be coupled to a power supply node, deactivating dummy p-device 208 and reducing the capacitance of gate 205.

It is noted that NMOS region 202 is a merged diffusion region in nanosheet 200. In other embodiments, PMOS regions could be merged leaving two NMOS regions. In such cases, dummy devices, e.g., dummy p-device 109, may be an n-channel device. Although subsequent diagrams depict a dummy p-device, similar circuits with dummy n-devices are possible and contemplated.

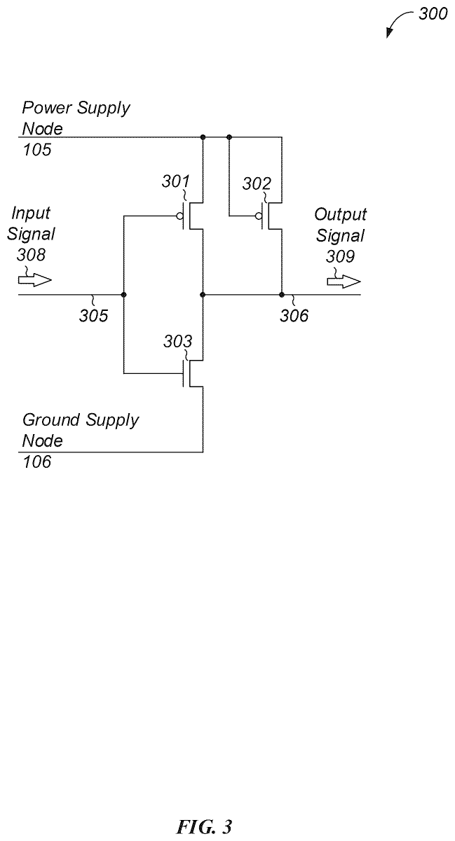

Turning to FIG. 3, a block diagram of an embodiment of a logic gate is depicted. As illustrated, logic gate 300 includes transistors 301-303. In various embodiments, logic gate 300 may correspond to logic gate 100 as depicted in FIG. 1 and transistor 301-303 may be included in a nanosheet, e.g., nanosheet 200 as depicted in FIG. 2. In some embodiments, transistor 302 may correspond to dummy p-device 109 as depicted in FIG. 1.

Transistors 301 and 302 are coupled between power supply node 105 and node 306, while transistor 303 is coupled between node 306 and ground supply node 106. Respective control terminals of transistors 301 and 303 are coupled to node 305 through which input signal 308 is received. Transistors 301 and 302 are configured, based on input signal 308, to selectively source current to or sink current from node 306 to generate output signal 309.

A control terminal of transistor 302 is coupled to power supply node 105, thereby deactivating transistor 302. By connecting the control terminal of transistor 302 to power supply node 105 instead of node 305, the capacitance of node 305 is reduced, which can improve performance of logic gate 300 despite the reduction in drive due to transistor 302 being deactivated.

In various embodiments, transistors 301 and 302 may be implemented as p-channel metal-oxide semiconductor field-effect transistors (“MOSFETs”), Fin field-effect transistors (“FinFETs”), gate-all-around field-effect transistors (“GAAFETs”), or any other suitable transconductance devices. In some embodiments, transistor 303 may be implemented as an n-channel MOSFET, FinFET, GAAFET, or any other suitable transconductance device.

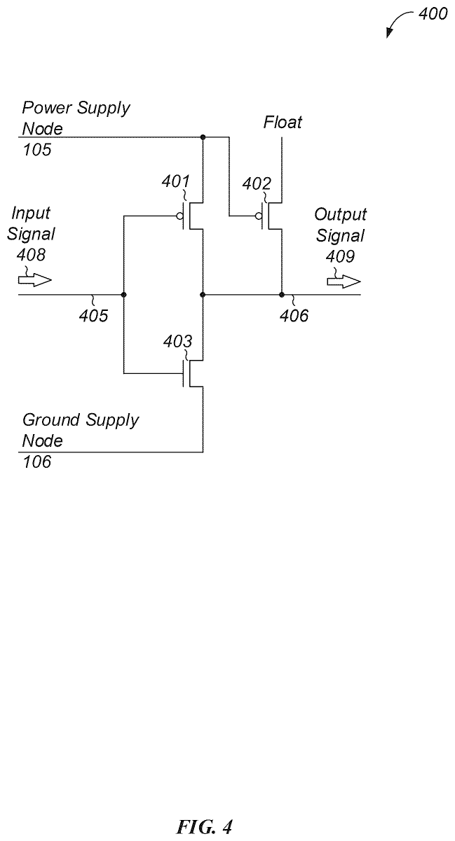

Turning to FIG. 4, a block diagram of an embodiment of a logic gate is depicted. As illustrated, logic gate 400 includes transistors 401-403. In various embodiments, logic gate 400 may correspond to logic gate 100 as depicted in FIG. 1 and transistor 401-403 may be included in a nanosheet, e.g., nanosheet 200 as depicted in FIG. 2. In some embodiments, transistor 402 may correspond to dummy p-device 109 as depicted in FIG. 1.

Transistor 401 is coupled between power supply node 105 and node 406, while transistor 403 is coupled between node 406 and ground supply node 106. Respective control terminals of transistors 401 and 403 are coupled to node 405 through which input signal 408 is received. Transistors 401 and 402 are configured, based on input signal 408, to selectively source current to or sink current from node 406 to generate output signal 409.

A drain terminal of transistor 402 is coupled to node 406, while a source terminal of transistor 402 is left electrically floating. A control terminal of transistor 402 is coupled to power supply node 105, thereby deactivating transistor 402. By connecting the control terminal of transistor 402 to power supply node 105 instead of node 405, the capacitance of node 405 is reduced, which can improve performance of logic gate 400 despite the reduction in drive due to transistor 402 being deactivated. Additionally, by electrically floating the source terminal of transistor 402, a leakage current through transistor 402 in its deactivated state is reduced.

In various embodiments, transistors 401 and 402 may be implemented as p-channel MOSFETs, FinFETs, GAAFETs, or any other suitable transconductance devices. In some embodiments, transistor 403 may be implemented as an n-channel MOSFET, FinFET, GAAFET, or any other suitable transconductance device.

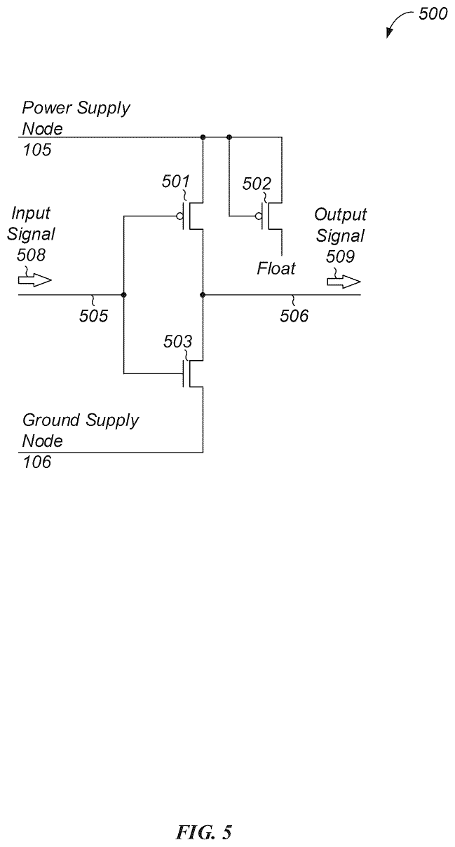

Turning to FIG. 5, a block diagram of an embodiment of a logic gate is depicted. As illustrated, logic gate 500 includes transistors 501-503. In various embodiments, logic gate 500 may correspond to logic gate 100 as depicted in FIG. 1 and transistor 501-503 may be included in a nanosheet, e.g., nanosheet 200 as depicted in FIG. 2. In some embodiments, transistor 502 may correspond to dummy p-device 109 as depicted in FIG. 1.

Transistor 501 is coupled between power supply node 105 and node 506, while transistor 503 is coupled between node 506 and ground supply node 106. Respective control terminals of transistors 501 and 503 are coupled to node 505 through which input signal 508 is received. Transistors 501 and 502 are configured, based on input signal 508, to selectively source current to or sink current from node 506 to generate output signal 509.

A source terminal of transistor 502 is coupled to power supply node 105, while a drain terminal of transistor 502 is left electrically floating. A control terminal of transistor 502 is coupled to power supply node 105, thereby deactivating transistor 502. By connecting the control terminal of transistor 502 to power supply node 105 instead of node 505, the capacitance of node 505 is reduced, which can improve performance of logic gate 500 despite the reduction in drive due to transistor 502 being deactivated. Additionally, by electrically floating the drain terminal of transistor 502, a leakage current through transistor 502 in its deactivated state is reduced.

In various embodiments, transistors 501 and 502 may be implemented as p-channel MOSFETs, FinFETs, GAAFETs, or any other suitable transconductance devices. In some embodiments, transistor 503 may be implemented as an n-channel MOSFET, FinFET, GAAFET, or any other suitable transconductance device.

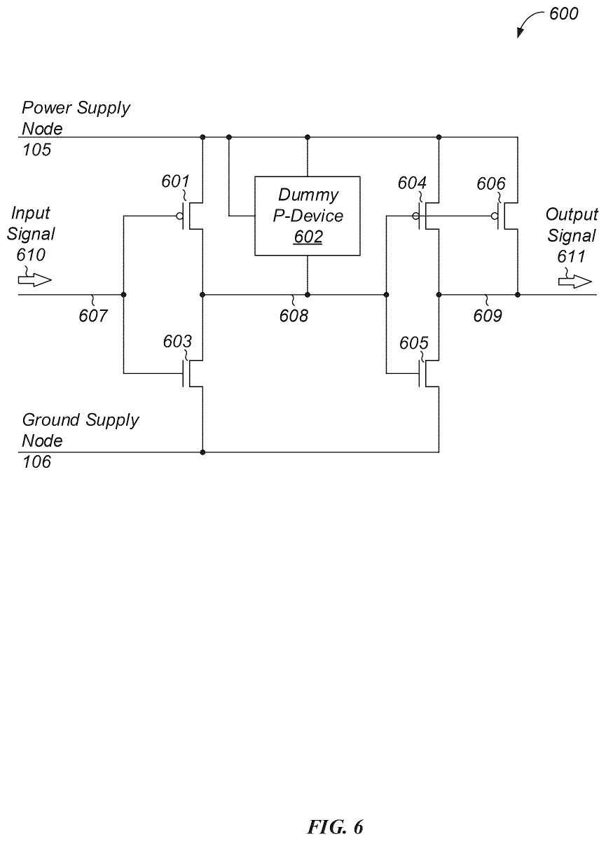

Turning to FIG. 6, a block diagram of an embodiment of a buffer circuit is depicted. As illustrated, buffer circuit 600 includes transistor 601, dummy p-device 602, and transistors 603-606. In various embodiments, transistor 601, dummy p-device 602, and transistors 603-606 may be included in a nanosheet, e.g., nanosheet 200 as depicted in FIG. 2. In some embodiments, dummy p-device 602 may correspond to dummy p-device 109 as depicted in FIG. 1.

Transistor 601 is coupled between power supply node 105 and node 608, while transistor 603 is coupled between node 608 and ground supply node 106. Respective control terminals of transistors 601 and 603 are coupled to node 607 through which input signal 610 is received.

Transistors 604 and 606 are coupled between power supply node 105 and node 609, while transistor 605 is coupled between node 609 and ground supply node 106. Respective control terminals of transistors 604-606 are coupled to node 608.

Dummy p-device 602 is coupled between power supply node 105 and node 608. A control terminal of dummy p-device 602 is coupled to power supply node 105. It is noted that dummy p-device 602 may be coupled in other ways, such as transistors 402 and 502 as depicted in FIGS. 4 and 5, respectively.

In various embodiments, transistors 601 and 603 are configured to operate as an inverter gate configured to generate a signal on node 608 that is a logical inverse of input signal 610. In a similar fashion, transistors 604-606 are also configured to operate as an inverter gate configured to generate output signal 611 such that it is a logical inverse of the signal on node 608.

In various embodiments, transistor 601, dummy p-device 602, transistor 604, and transistor 606 may be implemented as p-channel MOSFETs, FinFETs, GAAFETs, or any other suitable transconductance devices. In some embodiments, transistors 603 and 605 may be implemented as n-channel MOSFETs, FinFETs, GAAFETs, or any other suitable transconductance devices.

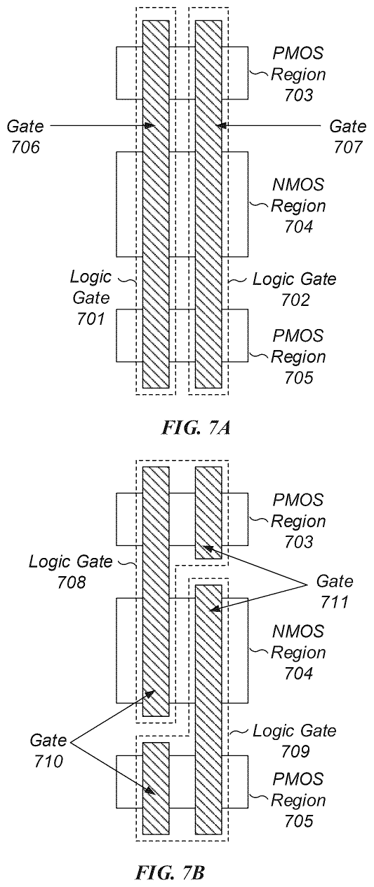

A block diagram of a different embodiment of a nanosheet is depicted in FIG. 7A. As illustrated, logic gate 701 is constructed from the transistors formed by gate 706 overlapping PMOS region 703, NMOS region 704, and PMOS region 705. In a similar fashion logic gate 702 is constructed from transistors formed by gate 707 overlapping PMOS region 703, NMOS region 704, and PMOS region 705.

As described above, the distance between PMOS region 703 and PMOS region 705 increases the length of gate 706, thereby increasing the capacitance at the control terminals of the transistors included in gate 706. In a similar fashion, control terminals of the transistors included in gate 707 also suffer from the increased capacitance.

Rather than converting one of the transistors from each of gate 706 and gate 707 to dummy devices, a different interconnect can be employed to reduce the pin capacitance of gates 706 and 707. FIG. 7B depicts an embodiment of a nanosheet with such interconnet.

In the embodiment of FIG. 7B, gate 710 and gate 711 are each split into two parts. Logic gate 708 is constructed with transistors formed at the overlap of gate 710 with PMOS region 703 and NMOS region 704, along with a transistor formed at the overlap of gate 711 with PMOS region 703. In a similar fashion, logic gate 709 is constructed with transistors formed at the overlap of gate 711 with NMOS region 704 and PMOS region 705, along with a transistor formed at the overlap of gate 710 with PMOS region 705.

By splitting gates 710 and 711 in the fashion depicted in FIG. 7B, logic gates 708 and 709 can be implemented with lower pin capacitance. The arrangement of FIG. 7B also allows for a larger aggregate p-channel device in each of logic gate 708 and logic gate 709.

In some semiconductor processes, a lowest level of metal (commonly referred to as “metal-0” or “m0”) can be used for interconnect between transistors. For example, metal-0 can be used to connect the output of a driver inverter to multiple load gates. In some cases, however, the resistance of metal-0 can adversely affect the performance of such a configuration.

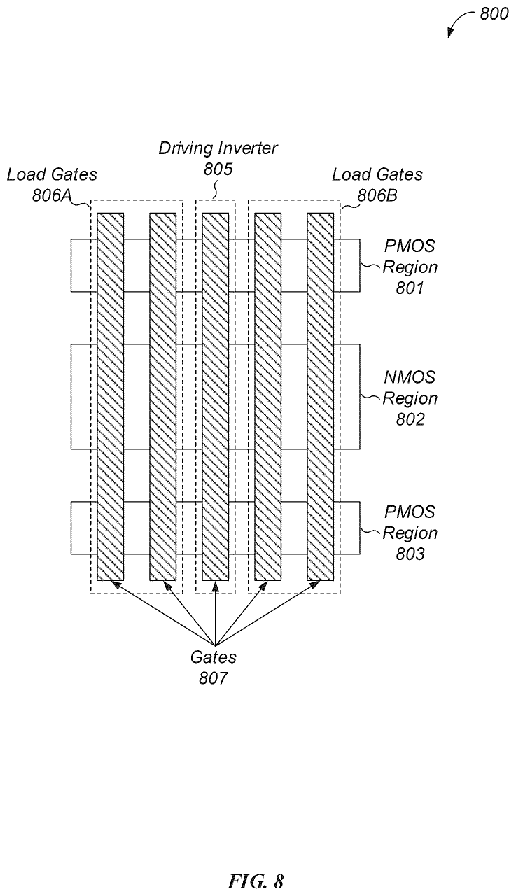

A technique to reduce the resistive load resulting from metal-0 routing, is depicted in FIG. 8. As illustrated, driver circuit 800 includes PMOS region 801, NMOS region 802, and PMOS region 803. Running orthogonally to PMOS region 801, NMOS region 802, and PMOS region 803 are gates 807.

Rather than grouping all of the load gates together, they are divided into load gates 806A and 806B. Driving inverter 805 is disposed between load gates 806A and 806B. In the present embodiment, driving inverter 805 drives both load gates 806A and 806B from the center both left and right as depicted in the figure. Using such an arrangement, the further load gate from driving inverter 805 is half the distance of an end-drive configuration, thereby reducing resistance of the interconnect and improving performance.

It is noted that this is merely an example. Other embodiments, with more load gates and additional diffusion regions are possible and contemplated.

To summarize, various embodiments of a logic gate implemented with transistors included in a nanosheet are disclosed. Broadly speaking, the nanosheet includes a plurality of diffusion regions that include a first p-type region, a second p-type region, and an n-type region, wherein the n-type region is disposed between the first p-type region and the second p-type region. The nanosheet further includes a plurality of gates disposed orthogonally to the plurality of diffusion regions and overlapping the first p-type region, the second p-type region, and the n-type region. The nanosheet includes a first transistor formed at a first overlap of a given gate of the plurality of gates and the first p-type region, a second transistor formed at a second overlap of the given gate and the n-type region, wherein a first control terminal of the first transistor and a second control terminal of the second transistor are coupled to an input node, and a third transistor formed at a third overlap of the given gate and the second p-type region, wherein a third control terminal of the third transistor is coupled to a power supply node

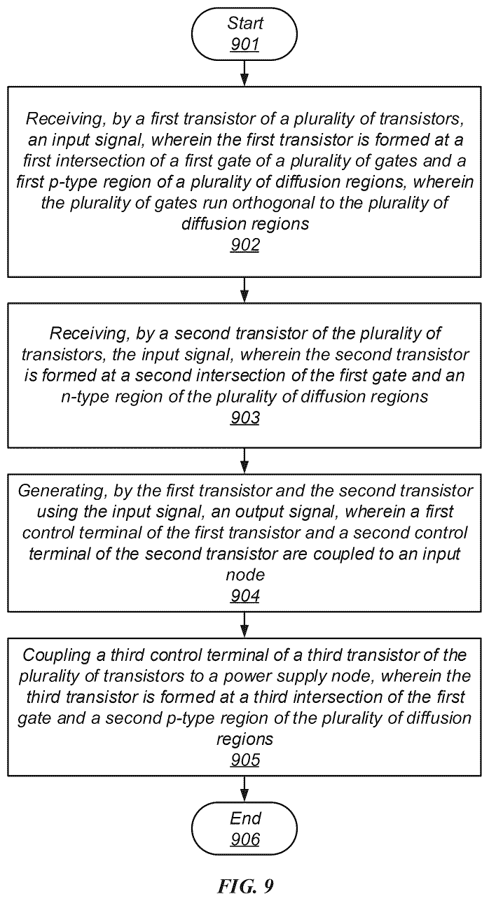

A flow diagram depicting an embodiment of a method for operating a logic gate is illustrated in FIG. 9. The method, which may be applied to various logic gates, e.g., logic gate 100 as depicted in FIG. 1, begins in block 901.

The method includes receiving, by a first transistor of a plurality of transistors, an input signal (block 902). In various embodiments, the first transistor is formed at a first intersection of a first gate of a plurality of gates and a first p-type region of a plurality of diffusion regions, where the plurality of gates run orthogonal to the plurality of diffusion regions.

The method also includes receiving, by a second transistor of the plurality of transistors, the input signal (block 903). In some embodiments, the second transistor is formed at a second intersection of the first gate and an n-type region of the plurality of diffusion regions.

The method further includes generating, by the first transistor and the second transistor using the input signal, an output signal (block 904). In various embodiments, a first control terminal of the first transistor and a second control terminal of the second transistor are coupled to an input node.

The method also includes coupling a third control terminal of a third transistor of the plurality of transistors to a power supply node (block 905). In some cases, the third transistor is formed at a third intersection of the first gate and a second p-type region of the plurality of diffusion regions.

In some embodiments, the n-type region is disposed between the first p-type region and the second p-type region. In various embodiments, a first drain terminal of the first transistor, a second drain terminal of the second transistor, and a third drain terminal of the third transistor are coupled to an output node, and where a source terminal of the third transistor is electrically floating.

In different embodiments, a first drain terminal of the first transistor and a second drain terminal of the second transistor are coupled to an output node, wherein a third drain terminal of the third transistor is electrically floating, and where a source terminal of the third transistor is coupled to the power supply node. In various embodiments, a first drain terminal of the first transistor, a second drain terminal of the second transistor, and a third drain terminal of the third transistor are coupled to an output node, where a source terminal of the third transistor is coupled to the power supply node. The method concludes in block 906.

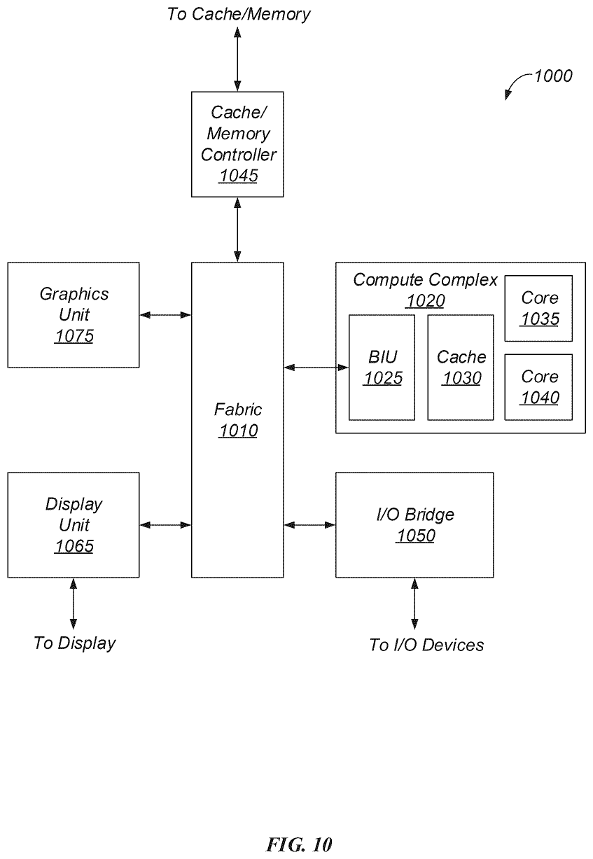

Referring now to FIG. 10, a block diagram illustrating an example embodiment of a device is shown. In some embodiments, elements of device 1000 may be included within a system-on-a-chip. In some embodiments, device 1000 may be included in a mobile device, which may be battery-powered. Therefore, power consumption by device 1000 may be an important design consideration. In the illustrated embodiment, device 1000 includes fabric 1010, compute complex 1020, input/output (I/O) bridge 1050, cache/memory controller 1045, graphics unit 1075, and display unit 1065. In some embodiments, device 1000 may include other components (not shown) in addition to, or in place of, the illustrated components, such as video processor encoders and decoders, image processing or recognition elements, computer vision elements, etc.

Fabric 1010 may include various interconnects, buses, MUX's, controllers, etc., and may be configured to facilitate communication between various elements of device 1000. In some embodiments, portions of fabric 1010 may be configured to implement various different communication protocols. In other embodiments, fabric 1010 may implement a single communication protocol, and elements coupled to fabric 1010 may convert from the single communication protocol to other communication protocols internally.

In the illustrated embodiment, compute complex 1020 includes bus interface unit (BIU) 1025, cache 1030, and cores 1035 and 1040. In various embodiments, compute complex 1020 may include various numbers of processors, processor cores, and caches. For example, compute complex 1020 may include 1, 2, or 4 processor cores, or any other suitable number. In one embodiment, cache 1030 is a set associative L2 cache. In some embodiments, cores 1035 and 1040 may include internal instruction and data caches. In some embodiments, a coherency unit (not shown) in fabric 1010, cache 1030, or elsewhere in device 1000, may be configured to maintain coherency between various caches of device 1000. BIU 1025 may be configured to manage communication between compute complex 1020 and other elements of device 1000. Processor cores, such as cores 1035 and 1040, may be configured to execute instructions of a particular instruction set architecture (ISA) which may include operating system instructions and user application instructions. These instructions may be stored in a computer readable medium such as a memory coupled to cache/memory controller 1045 as discussed below.

As used herein, the term “coupled to” may indicate one or more connections between elements, and a coupling may include intervening elements. For example, in FIG. 10, graphics unit 1075 may be described as “coupled to” a memory through fabric 1010 and cache/memory controller 1045. In contrast, in the illustrated embodiment of FIG. 10, graphics unit 1075 is “directly coupled” to fabric 1010 because there are no intervening elements.

Cache/memory controller 1045 may be configured to manage transfer of data between fabric 1010 and one or more caches and memories. For example, cache/memory controller 1045 may be coupled to an L3 cache, which may, in turn, be coupled to a system memory. In other embodiments, cache/memory controller 1045 may be directly coupled to a memory. In some embodiments, cache/memory controller 1045 may include one or more internal caches. Memory coupled to cache/memory controller 1045 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 1045 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 1020 to cause the computing device to perform functionality described herein.

Graphics unit 1075 may include one or more processors, e.g., one or more graphics processing units (GPUs). Graphics unit 1075 may receive graphics-oriented instructions, such as OPENGL®, Metal®, or DIRECT3D® instructions, for example. Graphics unit 1075 may execute specialized GPU instructions or perform other operations based on the received graphics-oriented instructions. Graphics unit 1075 may generally be configured to process large blocks of data in parallel, and may build images in a frame buffer for output to a display, which may be included in the device or may be a separate device. Graphics unit 1075 may include transform, lighting, triangle, and rendering engines in one or more graphics processing pipelines. Graphics unit 1075 may output pixel information for display images. Graphics unit 1075, in various embodiments, may include programmable shader circuitry which may include highly parallel execution cores configured to execute graphics programs, which may include pixel tasks, vertex tasks, and compute tasks (which may or may not be graphics-related).

Display unit 1065 may be configured to read data from a frame buffer and provide a stream of pixel values for display. Display unit 1065 may be configured as a display pipeline in some embodiments. Additionally, display unit 1065 may be configured to blend multiple frames to produce an output frame. Further, display unit 1065 may include one or more interfaces (e.g., MIPI® or embedded display port (eDP)) for coupling to a user display (e.g., a touchscreen or an external display).

I/O bridge 1050 may include various elements configured to implement universal serial bus (USB) communications, security, audio, and low-power always-on functionality, for example. I/O bridge 1050 may also include interfaces such as pulse-width modulation (PWM), general-purpose input/output (GPIO), serial peripheral interface (SPI), and inter-integrated circuit (I2C), for example. Various types of peripherals and devices may be coupled to device 1000 via I/O bridge 1050.

In some embodiments, device 1000 includes network interface circuitry (not explicitly shown), which may be connected to fabric 1010 or I/O bridge 1050. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 1000 with connectivity to various types of other devices and networks.

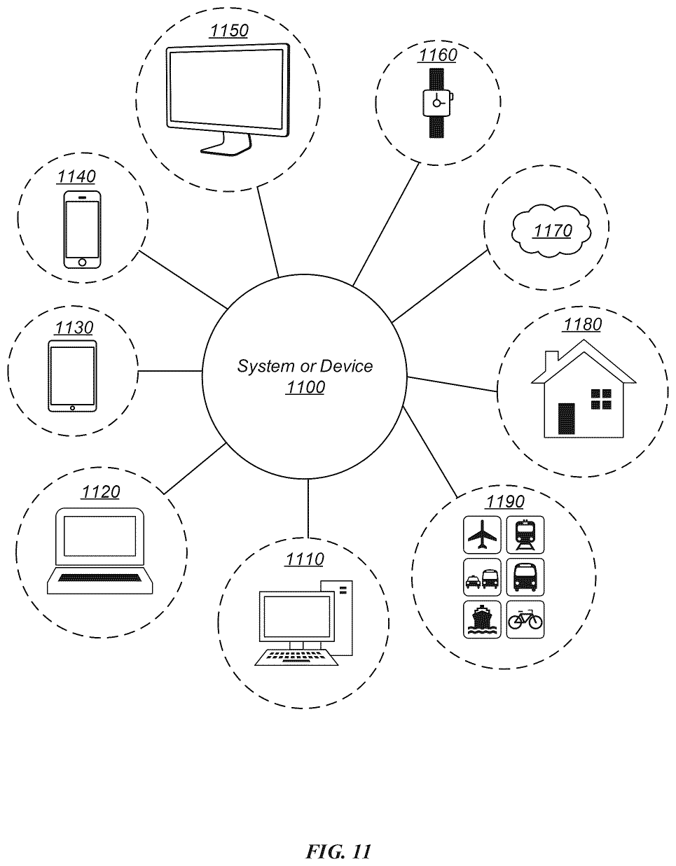

Turning now to FIG. 11, various types of systems that may include any of the circuits, devices, or systems discussed above are illustrated. System or device 1100, which may incorporate or otherwise utilize one or more of the techniques described herein, may be utilized in a wide range of areas. For example, system or device 1100 may be utilized as part of the hardware of systems such as a desktop computer 1110, laptop computer 1120, tablet computer 1130, cellular or mobile phone 1140, or television 1150 (or set-top box coupled to a television).

Similarly, disclosed elements may be utilized in a wearable device 1160, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 1100 may also be used in various other contexts. For example, system or device 1100 may be utilized in the context of a server computer system, such as a dedicated server or on shared hardware that implements a cloud-based service 1170. Still further, system or device 1100 may be implemented in a wide range of specialized everyday devices, including devices 1180 commonly found in the home such as refrigerators, thermostats, security cameras, etc. The interconnection of such devices is often referred to as the “Internet of Things” (IoT). Elements may also be implemented in various modes of transportation. For example, system or device 1100 could be employed in the control systems, guidance systems, entertainment systems, etc. of various types of vehicles 1190.

The applications illustrated in FIG. 11 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

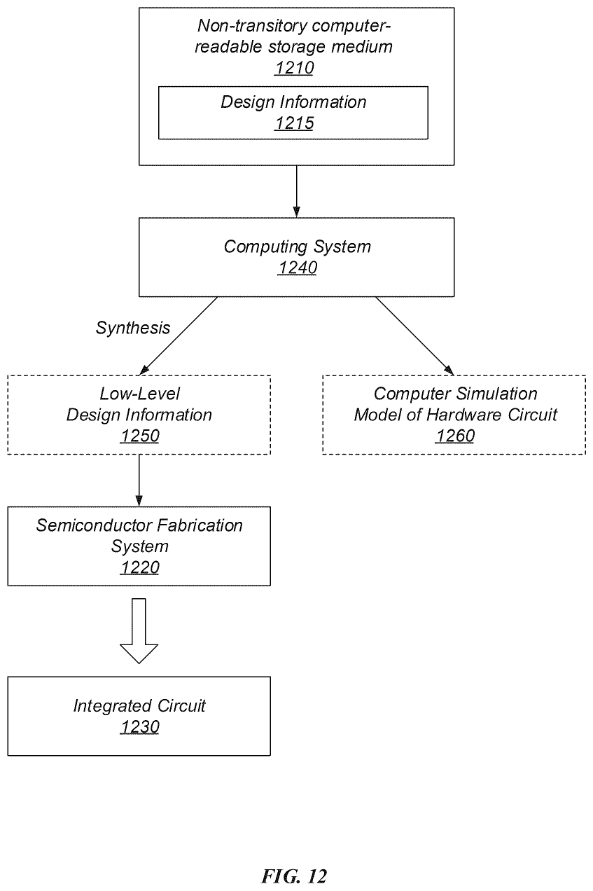

FIG. 12 is a block diagram illustrating an example of a non-transitory computer-readable storage medium that stores design information 1215, according to some embodiments. In the illustrated embodiment, computing system 1240 is configured to process design information 1215. This may include executing instructions included in design information 1215, interpreting instructions included in design information 1215, compiling, transforming, or otherwise updating design information 1215, etc. Therefore, design information 1215 controls computing system 1240 (e.g., by programming computing system 1240) to perform various operations discussed below, in some embodiments.

In the illustrated example, computing system 1240 processes design information 1215 to generate both computer simulation model of hardware circuit 1260 and low-level design information 1250. In other embodiments, computing system 1240 may generate only one of these outputs, may generate other outputs based on design information 1215, or both. Regarding computer simulation model of hardware circuit 1260, computing system 1240 may execute instructions of a hardware description language that includes register transfer level (RTL) code, behavioral code, structural code, or some combination thereof. The simulation model may perform the functionality specified by design information 1215, facilitate verification of the functional correctness of the hardware design, generate power consumption estimates, generate timing estimates, etc.

In the illustrated example, computing system 1240 also processes design information 1215 to generate low-level design information 1250 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 1250 (potentially among other inputs), semiconductor fabrication system 1220 is configured to fabricate integrated circuit 1230 (which may correspond to functionality of the computer simulation model of hardware circuit 1260). Note that computing system 1240 may generate different simulation models based on design information at various levels of description, including low-level design information 1250, design information 1215, and so on. The data representing low-level design information 1250 and computer simulation model of hardware circuit 1260 may be stored on non-transitory computer-readable storage medium 1210, or on one or more other media.

In some embodiments, low-level design information 1250 controls (e.g., programs) semiconductor fabrication system 1220 to fabricate integrated circuit 1230. Thus, when processed by the fabrication system, the design information may program the fabrication system to fabricate a circuit that includes various circuitry disclosed herein.

Non-transitory computer-readable storage medium 1210 may comprise any of various appropriate types of memory devices or storage devices. Non-transitory computer-readable storage medium 1210 may be an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash memory, magnetic media, e.g., a hard drive, or optical storage; registers, or other similar types of memory elements, etc. Non-transitory computer-readable storage medium 1210 may include other types of non-transitory memory as well, or combinations thereof. Accordingly, non-transitory computer-readable storage medium 1210 may include two or more memory media, which may reside in different locations—for example, in different computer systems that are connected over a network.

Design information 1215 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 1240, semiconductor fabrication system 1220, or both. In some embodiments, design information 1215 may also include one or more cell libraries that specify the synthesis, layout, or both of integrated circuit 1230. In some embodiments, design information 1215 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 1230 may, in various embodiments, include one or more custom macrocells, such as memories, analog or mixed-signal circuits, and the like. In such cases, design information 1215 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 1220 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1220 may also be configured to perform various testing of fabricated circuits for correct operation.

In various embodiments, integrated circuit 1230 and computer simulation model of hardware circuit 1260 are configured to operate according to a circuit design specified by design information 1215, which may include performing any of the functionality described herein. For example, integrated circuit 1230 may include any of various elements shown in FIGS. 1-8. Further, integrated circuit 1230 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 1215. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 1215 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 1250. Low-level design information 1250 may program semiconductor fabrication system 1220 to fabricate integrated circuit 1230.

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors, or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for”[performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a plurality of diffusion regions including a first p-type region, a second p-type region, and an n-type region, wherein the n-type region is disposed between the first p-type region and the second p-type region;
a plurality of gates disposed orthogonally to the plurality of diffusion regions and overlapping the first p-type region, the second p-type region, and the n-type region;
a first transistor formed at a first overlap of a given gate of the plurality of gates and the first p-type region;
a second transistor formed at a second overlap of the given gate and the n-type region, wherein a first control terminal of the first transistor and a second control terminal of the second transistor are coupled to an input node; and
a third transistor formed at a third overlap of the given gate and the second p-type region, wherein a third control terminal of the third transistor is coupled to a power supply node.

2. The apparatus of claim 1, wherein a first drain terminal of the first transistor, a second drain terminal of the second transistor, and a third drain terminal of the third transistor are coupled to an output node, and wherein a source terminal of the third transistor is electrically floating.

3. The apparatus of claim 1, wherein a first drain terminal of the first transistor and a second drain terminal of the second transistor are coupled to an output node, wherein a third drain terminal of the third transistor is electrically floating, and wherein a source terminal of the third transistor is coupled to the power supply node.

4. The apparatus of claim 1, wherein a first drain terminal of the first transistor, a second drain terminal of the second transistor, and a third drain terminal of the third transistor are coupled to an output node, wherein a source terminal of the third transistor is coupled to the power supply node.

5. The apparatus of claim 1, wherein a source terminal of the first transistor is coupled to the power supply node and a drain terminal of the first transistor is coupled to an output node, and wherein the first transistor is configured, based on a voltage of the input node, to source a current from the power supply node to the output node.

6. The apparatus of claim 1, wherein a source terminal of the second transistor is coupled to a ground supply node and a drain terminal of the second transistor is coupled to an output node, and wherein the second transistor is configured, based on a voltage of the input node, to sink a current from the output node to the ground supply node.

7. A method, comprising:
receiving, by a first transistor of a plurality of transistors, an input signal, wherein the first transistor is formed at a first intersection of a first gate of a plurality of gates and a first p-type region of a plurality of diffusion regions, wherein the plurality of gates run orthogonal to the plurality of diffusion regions;
receiving, by a second transistor of the plurality of transistors, the input signal, wherein the second transistor is formed at a second intersection of the first gate and an n-type region of the plurality of diffusion regions;
generating, by the first transistor and the second transistor using the input signal, an output signal, wherein a first control terminal of the first transistor and a second control terminal of the second transistor are coupled to an input node; and
coupling a third control terminal of a third transistor of the plurality of transistors to a power supply node, wherein the third transistor is formed at a third intersection of the first gate and a second p-type region of the plurality of diffusion regions.

8. The method of claim 7, wherein the n-type region is disposed between the first p-type region and the second p-type region.

9. The method of claim 7, wherein a first drain terminal of the first transistor, a second drain terminal of the second transistor, and a third drain terminal of the third transistor are coupled to an output node, and wherein a source terminal of the third transistor is electrically floating.

10. The method of claim 7, wherein a first drain terminal of the first transistor and a second drain terminal of the second transistor are coupled to an output node, wherein a third drain terminal of the third transistor is electrically floating, and wherein a source terminal of the third transistor is coupled to the power supply node.

11. The method of claim 7, wherein a first drain terminal of the first transistor, a second drain terminal of the second transistor, and a third drain terminal of the third transistor are coupled to an output node, wherein a source terminal of the third transistor is coupled to the power supply node.

12. The method of claim 7, coupling a first source terminal of the first transistor is to the power supply node, coupling a first drain terminal of the first transistor to an output node, and sourcing, by the first transistor, based on a voltage of the input node, to source a first current from the power supply node to the output node.

13. The method of claim 12, coupling a second source terminal of the second transistor to the output node, coupling a second drain terminal of the second transistor to a ground supply node, and sinking, by the second transistor, based on the voltage of the input node, a second current from the output node to the ground supply node.

14. A system, comprising:
a plurality of circuit blocks, including a particular circuit block that includes a plurality of transistors, wherein a first control terminal of a first transistor of the plurality of transistors and a second control terminal of a second transistor of the plurality of transistors is coupled to an input node, wherein the first transistor and the second transistor are configured to:
receive an input signal; and
generate an output signal using the input signal; and
wherein the first transistor is formed at an intersection of a first gate of a plurality of gates included in the particular circuit block and a first p-type diffusion region of a plurality of diffusion regions included in the particular circuit block, wherein the plurality of gates run orthogonal to the plurality of diffusion regions;
wherein the second transistor is formed at a second intersection of the first gate and an n-type diffusion region of the plurality of diffusion regions;
wherein a third control terminal of a third transistor of the plurality of transistors is coupled to a power supply node; and
wherein the third transistor is formed at a third intersection of the first gate and a second p-type diffusion region of the plurality of diffusion regions.

15. The system of claim 14, wherein the n-type diffusion region is disposed between the first p-type diffusion region and the second p-type diffusion region.

16. The system of claim 14, wherein a first drain terminal of the first transistor, a second drain terminal of the second transistor, and a third drain terminal of the third transistor are coupled to an output node, and wherein a source terminal of the third transistor is electrically floating.

17. The system of claim 14, wherein a first drain terminal of the first transistor and a second drain terminal of the second transistor are coupled to an output node, wherein a third drain terminal of the third transistor is electrically floating, and wherein a source terminal of the third transistor is coupled to the power supply node.

18. The system of claim 14, wherein a first drain terminal of the first transistor, a second drain terminal of the second transistor, and a third drain terminal of the third transistor are coupled to an output node, wherein a source terminal of the third transistor is coupled to the power supply node.

19. The system of claim 14, wherein a first source terminal of the first transistor is coupled to the power supply node and a drain terminal of the first transistor is coupled to an output node, and wherein the first transistor is configured, based on a voltage of the input node, to source a first current from the power supply node to the output node.

20. The system of claim 19, wherein a second source terminal of the second transistor is coupled to the output node, and a second drain terminal of the second transistor is coupled to a ground supply node, and wherein the second transistor is configured, based on the voltage of the input node, to sink a second current from the output node to the ground supply node.
